(19) United States
(12) Patent Application Publication
(10) Pub. No.: US 2025/0357250 A1
(43) Pub. Date: Nov. 20, 2025

(54) METHOD FOR FORMING THERMAL CONDUCTOR MATERIAL FILM AND STACKING STRUCTURE FORMD THEREWITH

(71) Applicant: Taiwan Semiconductor Manufacturing Company, Ltd., Hsinchu (TW)

(72) Inventors: Ji CUI, Bolingbrook, IL (US); Shih-Hao Tseng, Hsinchu City (TW); Chen-Hua Yu, Hsinchu City (TW)

(73) Assignee: Taiwan Semiconductor Manufacturing Company, Ltd., Hsinchu (TW)

(21) Appl. No.: 18/666,761

(22) Filed: May 16, 2024

(51) Int. Cl. H01L 23/373; H01L 21/02; H01L 21/3105; H01L 23/00

(52) U.S. Cl. CPC H01L 23/3732; H01L 21/02115; H01L 21/31053; H01L 24/08; H01L 24/80; H01L 2224/08145; H01L 2224/80895; H01L 2224/80896

(57) ABSTRACT

A manufacturing method for forming a thermal conductor material film and a stacking structure formed therewith are provided. The stacking structure includes a first die and a second die stacked on the first die. The first die includes a first substrate, a first dielectric layer located over the first substrate, and a first bonding structure located in the first dielectric layer and over the first substrate. The first dielectric layer includes a composite thermal conductor material film, and the composite thermal conductor material film has a diamond containing surface.

### BACKGROUND

In semiconductor manufacturing technologies, semiconductor structures incorporating different types of semiconductor dies are fabricated and integrated with integrated circuits (ICs) and electronic devices. It is important to establish reliable electrical inter-connection and to balance heat dissipation requirements between the semiconductor dies and/or other devices to offer durable integration.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E are schematic cross-sectional views showing various stages of a manufacturing method for forming a thermal conductor material film over a base structure according to some embodiments of the present disclosure.

FIG. 2 is a process flow diagram showing the process steps of the manufacturing method for forming a thermal conductor material film over a base structure according to some embodiments of the present disclosure.

FIG. 3 is a schematic top view showing the surface of the composite film according to some embodiments of the present disclosure.

FIGS. 4A-4D are schematic cross-sectional views showing various stages of a manufacturing method for forming a thermal conductor material film over a base structure according to some embodiments of the present disclosure.

FIG. 5 is a process flow diagram showing the process steps of the manufacturing method for forming a thermal conductor material film over a base structure according to some embodiments of the present disclosure.

FIGS. 6-9 are schematic cross-sectional views showing various stages of a manufacturing method for forming a stacking structure according to some embodiments of the present disclosure.

FIG. 10 is an enlarged cross-sectional view showing a bonding portion relative to the underneath element(s) within the stacking structure according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the present disclosure provides applicable concepts that can be embodied in a wide variety of specific contexts. The specific embodiment(s) discussed herein is merely illustrative and is related to a three-dimensional (3D) integration structure or assembly, and does not limit the scope of the present disclosure. Embodiments of the present disclosure describe the exemplary manufacturing process of 3D stacking structures and the 3D stacking structures fabricated there-from. Certain embodiments of the present disclosure are related to the 3D stacking structures formed with wafer bonding structures and stacked wafers and/or dies. Other embodiments relate to 3D integration structures or assemblies including post-passivation interconnect (PPI) structures or interposers with other electrically connected components, including wafer-to-wafer assembled structures, die-to wafer assembled structures, package-on-package assembled structures, die-to-die assembled structures, and die-to-substrate assembled structures. The wafers or dies may include one or more types of integrated circuits or electrical components on a bulk semiconductor substrate or a silicon/germanium-on-insulator substrate. The embodiments are intended to provide further explanations but are not used to limit the scope of the present disclosure.

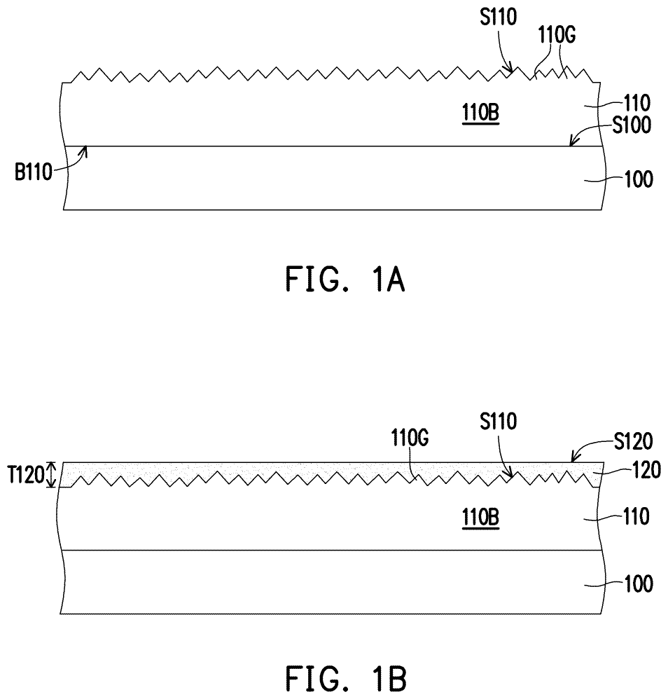

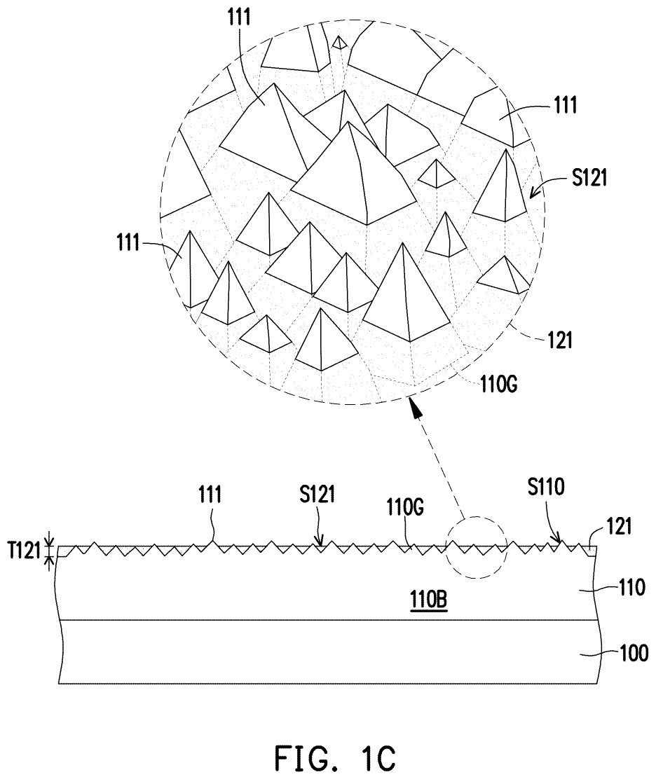

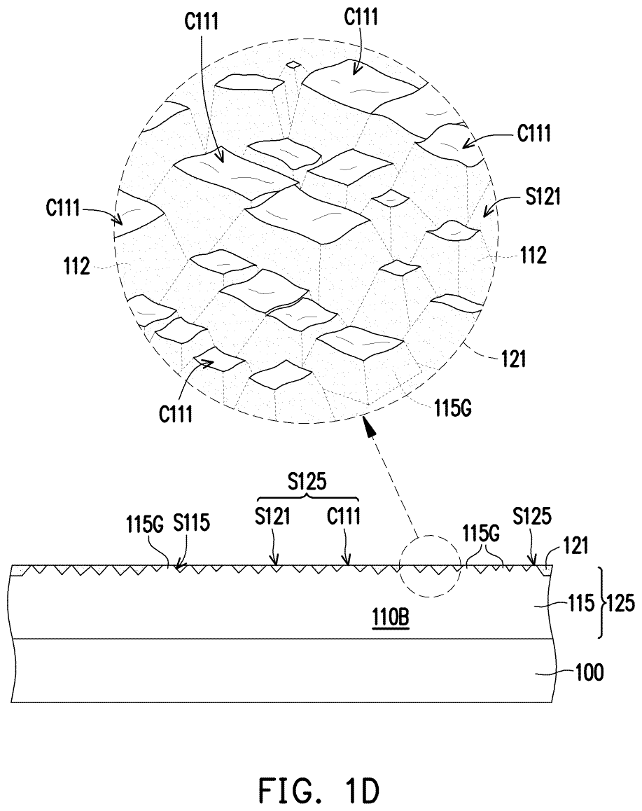

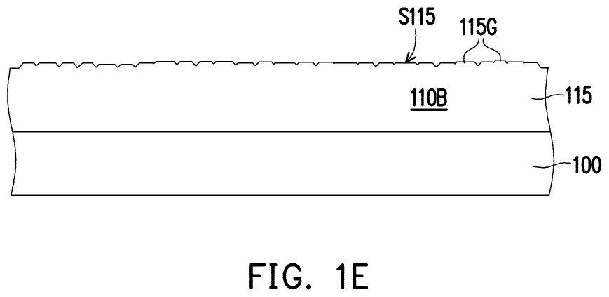

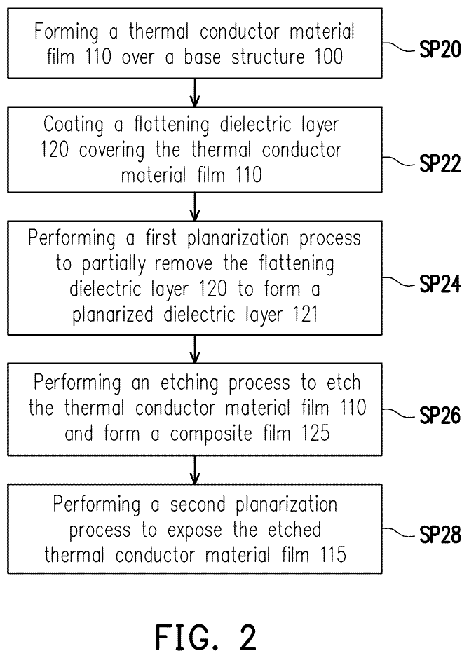

FIGS. 1A-1E are schematic cross-sectional views showing various stages of a manufacturing method for forming a thermal conductor material film over a base structure according to some embodiments of the present disclosure. FIG. 2 is a process flow diagram showing the process steps of the manufacturing method for forming a thermal conductor material film over a base structure according to some embodiments of the present disclosure.

Referring to FIG. 1A and FIG. 2, in Step SP20, a thermal conductor material film 110 is formed over a base structure 100. In FIG. 1A, the base structure 100 is firstly provided. In some embodiments, the base structure 100 includes multiple dielectric layers formed over a semiconductor substrate having a plurality of transistors formed therein. In some embodiments, the base structure 100 provided may be used to form a semiconductor stacking structure through semiconductor manufacturing processes or to form a package structure through packaging processes. In some embodiments, the base structure 100 may be provided in a wafer form including multiple dies units defined or formed within. In some embodiments, the base structure 100 provided in a wafer form may be a semiconductor bulk wafer with active devices and optional passive devices formed therein. In some embodiments, the base structure 100 provided in a wafer form may be a reconstructed wafer including multiple semiconductor dies encapsulated in a molding compound. In some embodiments, the multiple dies included in the base structure 100 provided in a wafer form may have the same design and performing the same function. In some embodiments, the multiple dies included in the base structure 100 provided in a wafer form may have different designs and performing different functions.

Referring to FIG. 1A and FIG. 2, in Step SP20, the thermal conductor material film 110 is formed on the base structure 100 and formed blanketly over a top surface S100 of the base structure 100. In some embodiments, the thermal conductor material film 110 is or includes a film of a high thermal conductivity material, above 100 W/(m·K) at room temperature(s), such as diamond. Diamond having a high thermal conductivity, up to 2,200 W/(m·K), is one of the most potential materials used as heat transferring films for heat dissipation or used for developing high-efficiency heat spreaders for integrated circuits, high power transistors, or other electronic components with high thermal dissipation needs. In some embodiments, the thermal conductor material film 110 is formed of crystalline diamond by chemical vapor deposition (CVD). In one embodiment, the thermal conductor material film 110 is made of diamond formed by CVD technique using hydrocarbon gas mixtures to create a carbon plasma, and carbon atoms are deposited and built up over an underlying layer or substrate to form diamond having a crystalline structure. Herein, the crystalline diamond includes polycrystalline diamond in various grain sizes such as micro-crystalline diamond and nano-crystalline diamond. Any applicable method suitable for forming diamond may be used, and is not limited to the fabrication method described herein.

Referring to FIG. 1A, in some embodiments, the thermal conductor material film 110 (e.g. a diamond film) is formed as a homogenous and continuous film formed of nanometric grains (and aggregates) of diamond and has a non-smooth gritty surface S110. For example, through CVD, the deposited crystalline diamond film has a non-smooth and uneven surface formed of faceted micro- or nano-metric grains. In some embodiments, the thermal conductor material film 110 formed of crystalline diamond grains and the thermal conductor material film 110 includes the base portion 110B and grainy portions 110G. Referring to FIG. 1A, the grainy portions 110G of the thermal conductor material film 110 create a rugged and faceted surface S110 (illustrated as valleys and peaks or zigzag-shaped in the schematic cross-sectional view) with a surface roughness of R1. In FIG. 1A, the gritty surface S110 refers to the top surface of the thermal conductor material film 110, opposite to the bottom surface B110 facing and in contact with the base structure 100. In some embodiments, the surface roughness R1 ranges from about 0.1 microns to about 3 microns. For example, the estimation of the surface roughness before or after treatments (such as polishing, etching, and/or deposition) is obtained by profilometry measurements, and values of the arithmetic average roughness (Ra) may be estimated.

Referring to FIG. 1B and FIG. 2, in Step SP22, a flattening dielectric layer 120 is formed on the thermal conductor material film 110 fully covering the whole surface S110 of the thermal conductor material film 110. In some embodiments, the flattening dielectric layer 120 is formed from a flowable low-k dielectric material so as to completely cover the uneven surface S110 and the flattening dielectric layer 120 is formed with a smooth and even surface S120. In one embodiment, the flattening dielectric layer 120 is formed with a thickness of T120. In some embodiments, the flattening dielectric layer 120 is formed by coating such as spin-coating, or sol-gel processing, and then through one or more annealing process, preferably a lower temperature thermal process under 150-250 degrees Celsius and a higher temperature thermal process above 300 degrees Celsius. In some embodiments, the flattening dielectric layer 120 is formed by CVD such as flowable CVD.

In some embodiments, the material of the flattening dielectric layer 120 is or includes one or more spin-on dielectric (SOD) materials. Spin-on dielectric materials include flowable oxide materials, such as flowable silicate glass materials (undoped silicate glass (USG) or phosphate silicate glass (PSG)), colloidal silica, siloxane compound materials or mixtures thereof. Due to the flowability, SODs are applied via spin-coating to improve topside planarity (flattening) and to provide a smooth and flat surface.

In some embodiments, the material(s) of the flattening dielectric layer 120 includes silicon oxide such as TEOS oxide, or any other dielectric materials including but not limited to silicon nitride, silicon oxynitride, silicon carbonitride (SiCN), or other silicon based dielectric materials with atoms O, C, or N in varying ratios. The material(s) of the flattening dielectric layer 120, being organic or inorganic, has a low-dielectric constant (low-K), provides good gap fill and planarity through coating and has low moisture uptake for better moisture protection.

Referring to FIG. 1C and FIG. 2, in Step SP24, a planarization process (first planarization process) is performed to partially remove the flattening dielectric layer 120 to become the planarized dielectric layer 121. In some embodiments, the planarization process includes a chemical mechanical polishing (CMP) process using the suitable polishing pad and abrasives to selectively remove the material of the flattening dielectric layer 120 without removing or minimally removing the thermal conductor material film 110. In some embodiments, the CMP process is performed using a polishing pad with a Shore D hardness larger than 50 and a down force larger than 2 psi for a high throughput process to remove the spin-on dielectrics or other flattening dielectric material while revealing the non-smooth surface S110. Herein, such planarization process (first planarization process) may be referred to as a high throughput planarization process. For example, when the thermal conductor material film 110 is made of diamond of very high hardness, such planarization process is unlikely to remove the thermal conductor material film 110 but easily removes the softer dielectric material of the flattening dielectric layer 120. In FIG. 1C, during the planarization process, the flattening dielectric layer 120 is partially removed with a polished surface S121 and is polished downward to a reduced thickness T121, so that the grainy portions 110G of the thermal conductor material film 110 are exposed from the polished surface S121. Herein, T121 is smaller than T120, and T121 may be about or less than half of T120.

As seen at upper right part of FIG. 1C, a schematic partial enlarged view of the surface topography of the underlying thermal conductor material film 110 exposed from the polished surface S121 after the planarization process is shown. In the schematic partial enlarged view of FIG. 1C, the small and large pyramids (or cones) representing the facets of the diamond crystals or grains (e.g. grainy portions 110G) of the underlying thermal conductor material film 110, it is seen that the peak portions (sharp points or tips) 111 of the grains (grainy portions 110G) in the thermal conductor material film 110 are protruded out of the polished surface S121 and exposed from the polished surface S121 of the planarized dielectric layer 121.

Referring to FIG. 1D and FIG. 2, in Step SP26, an etching process is performed to etch the thermal conductor material film 110 and form a composite film 125. Referring to FIG. 1C and FIG. 1D, the etching process is performed toward the polished surface S121 to etch portions (peak portions 111) of the thermal conductor material film 110 that are exposed from the polished surface S121. In some embodiments, the etching process includes performing a plasma etching process using oxygen containing plasma such as oxygen (O₂) plasma or ozone (O₃) plasma. In some embodiments, the etching process uses etchants including fluorine-containing compounds. In Step SP26, the etching process selectively removes the material of the thermal conductor material film 110. In some embodiments, the etching process performed shows a higher etching rate toward the thermal conductor material film 110 and a much lower etching rate toward the dielectric layer 121 (or the flattening dielectric layer 120). In some embodiments, the etching process performed shows a higher etching rate (at least 10 times) for the thermal conductor material film 110, relative to the etching rate for the flattening dielectric layer 120. In some embodiments, when the thermal conductor material film 110 made of diamond and the flattening dielectric layer 120 made of an organic dielectric or polymeric material(s), the etching process exhibits a high etching selectivity to diamond, for example, the etching selectivity ranging from about 100:1 (diamond:dielectric) to about 10:1 (diamond:dielectric). In some embodiments, the end point of the etching process may be determined by monitoring the surface roughness in real-time and/or in a time-control mode.

As seen in FIG. 1D, the etching process selectively removes the exposed tips of the grain portions 110G of the thermal conductor material film 110 (i.e., removing the peak portions 111 of the grains in the film 110 in FIG. 1C), the grainy thermal conductor material film 110 is etched to become the etched thermal conductor material film 115 with the surface S115 that is smoother and less gritty than the gritty surface S110.

As seen at upper right part of FIG. 1D, a schematic partial enlarged view of the surface topography of the etched thermal conductor material film 115 exposed from the polished surface S121 after the treatment of the etching process is shown, it is seen that etched surfaces C111 of the remained foot portions 112 of the diamond grains (depicted as truncated pyramids) are revealed from the planarized surface S121 as the peak portions 111 (in FIG. 1C) of the grainy portions 110G in the thermal conductor material film 110 protruded out of or exposed from the polished surface S121 of the planarized dielectric layer 121 are removed (etched off) during the etching process. In some embodiments, through the selective etching process, the grainy thermal conductor material film 110 becomes the etched thermal conductor material film 115, as the grainy portions 110G of the thermal conductor material film 110 are flattened and become mesa portions 115G located above the base portion 110B of the etched thermal conductor material film 115.

Due to the high etching selectivity of the etching process, the planarized dielectric layer 121 is minimally etched and the polished surface S121 of the planarized dielectric layer 121 remains intact (substantially flat). Through the well-controlled etching process and for obtaining the minimum of the surface roughness, the etched surfaces C111 are mainly and largely levelled with the surface S121 and are joined to form a joined surface S125. In some embodiments, the plasma etching process may be isotropic etching, and the etched surfaces C111 are smoothly curved surfaces. In some embodiments, the plasma etching process may be anisotropic etching, and the etched surface C111 are substantially flat surfaces.

In some embodiments, as seen in FIG. 1D, after performing the etching process, a composite film 125 composed of the planarized dielectric layer 121 and the etched thermal conductor material film 115 is obtained, and the surface roughness R2 of the joined surface S125 of the composite film 125 is reduced by at least one third or more of the surface roughness R1 of the untreated thermal conductor material film 110. In some embodiments, the surface roughness R2 is decreased to about half of the surface roughness R1, or decreased to about one third (or lower) of the surface roughness R1 of the untreated thermal conductor material film 110. In some embodiments, the surface roughness R2 is about or less than about 1 micron. In some embodiments, the surface roughness R2 is about or less than 200 nm. In some embodiments, the surface roughness R2 is about or less than 10 nm.

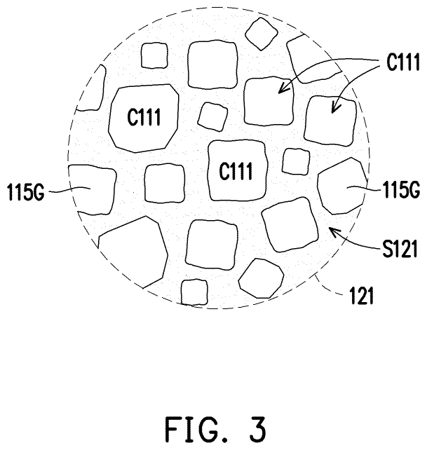

Following the process steps SP20-SP26, a composite film 125 is formed with a quite flat and levelled surface S125 of a small surface roughness R2. In some embodiments, the composite surface S125 is a diamond containing surface. Referring to FIG. 1D and FIG. 3, for the composite film 125, the planarized dielectric layer 121 fills in the cavities (or valleys) between the sporadically distributed grains (e.g. mesa portions 115G) of the etched thermal conductor material film 115. From the schematic top view of FIG. 3, it is seen that the separated etched surfaces C111 of the etched thermal conductor material film 115 are joined with the planarized surface S121 of the planarized dielectric layer 121 to form the composite surface S125. That is, in the composite film 125 consisting of the thermal conductor material film 115 and the dielectric layer 121 stacked on the thermal conductor material film 115, the mesa portions 115G of the thermal conductor material film 115 are surrounded by the dielectric layer 121 but are exposed from the dielectric layer 121, and the surfaces C111 of the mesa portions 115G are flush with and substantially levelled with the surfaces S121 of the dielectric layer 121. In some embodiments, the composite surface S125 is a diamond containing surface.

Following the process steps SP20-SP26, the surface roughness of the obtained composite film 125 is minimized with a substantially smooth surface S125, thus enhancing the adhesion and bonding strength of the composite film. In some embodiments, for the composite film offering a very low surface roughness, the thermal conductor material (such as diamond) exposed from the surface of the composite film can assist heat transfer efficiently and function as heat spreader, while the dielectric layer can increase the adhesion of the composite surface and enhance the bonding adhesion between the composite surface (e.g. diamond containing surface) of the composite film and other surfaces of the adjacent layers or components. The composite film offers high thermal conductivity and functions as a high-quality thermal conductor material film (due to the diamond film) along with better planarity and surface smoothness for backend of line (BEOL) interconnect structures and package structures.

Referring to FIG. 1E and FIG. 2, in Step SP28, another planarization process (second planarization process) is performed to remove the dielectric layer 121 (FIG. 1D). In some embodiments, Step SP28 may be omitted, if the composite film is preferred. In some embodiments, the planarization process includes a chemical mechanical polishing (CMP) process using the suitable polishing pad and abrasives to selectively remove the material of the remained dielectric layer 121 without removing or minimally removing the etched thermal conductor material film 115. In some embodiments, the CMP process is performed using a polishing pad with a Shore D hardness smaller than 50 and a down force less than 2 psi to remove the residual dielectrics (the flattening dielectric material) to reveal the smoother surface S115 of the etched thermal conductor material film 115. Herein, such planarization process (second planarization process) may be referred to as a gentle planarization process. For example, when the thermal conductor material film 110 is made of diamond of very high hardness, such planarization process is unlikely to remove the etched thermal conductor material film 115 but easily removes the softer dielectric material of the remained dielectric layer 121.

In FIG. 1E, in some embodiments, during the planarization process, the remained dielectric layer 121 is completely removed and the surface S115 of the etched thermal conductor material film 115 is exposed. In some embodiments, through the selective etching process, the surface S115 is smoother than the untreated gritty surface S110, and a surface roughness R3 of the surface S115 of the etched thermal conductor material film 115 is reduced by at least one third or more of the surface roughness R1 of the untreated thermal conductor material film 110. In some embodiments, the surface roughness R3 is decreased to about half of the surface roughness R1, or decreased to about one third (or lower) of the surface roughness R1 of the untreated thermal conductor material film 110. In some embodiments, the surface roughness R3 is larger (rougher) than the surface roughness R2 of the composite film 125.

Following the process steps SP20-SP28, the surface roughness R3 of the obtained thermal conductor material film 115 is significantly improved (becomes lower) and the surface S115 of the obtained thermal conductor material film 115 becomes less gritty and smoother, thus improving the film quality. Though the previously described process steps, it is possible to form high quality thermal conductor material film (e.g. diamond film) with better planarity and surface smoothness under processing conditions compatible with backend of line (BEOL) processes without using high temperature conditions or sintering techniques. By doing so, the thermal conductor material film of high thermally conductivity may be incorporated within the BEOL structures and package structures.

After forming and obtaining diamond films with low surface roughness over the wafer (or dies/chiplets), additional dielectric bond film can also be deposited to increase the bonding adhesion between the diamond containing surface of the wafer (or dies/chiplets) and the other surfaces of another wafer or dies. The material of the dielectric bond film may include silicon oxide, silicon nitride, silicon oxynitride, silicon carbonitride, or other silicon based dielectric materials with O, C, N atoms in varying ratios.

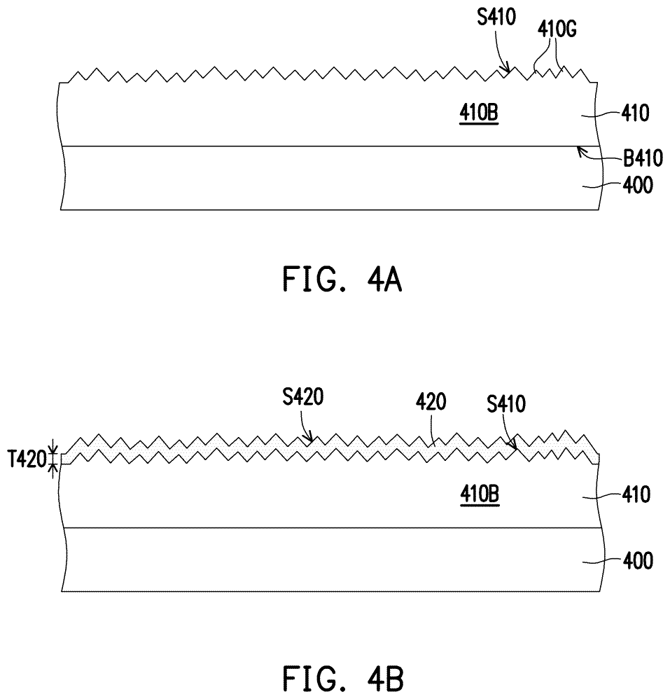

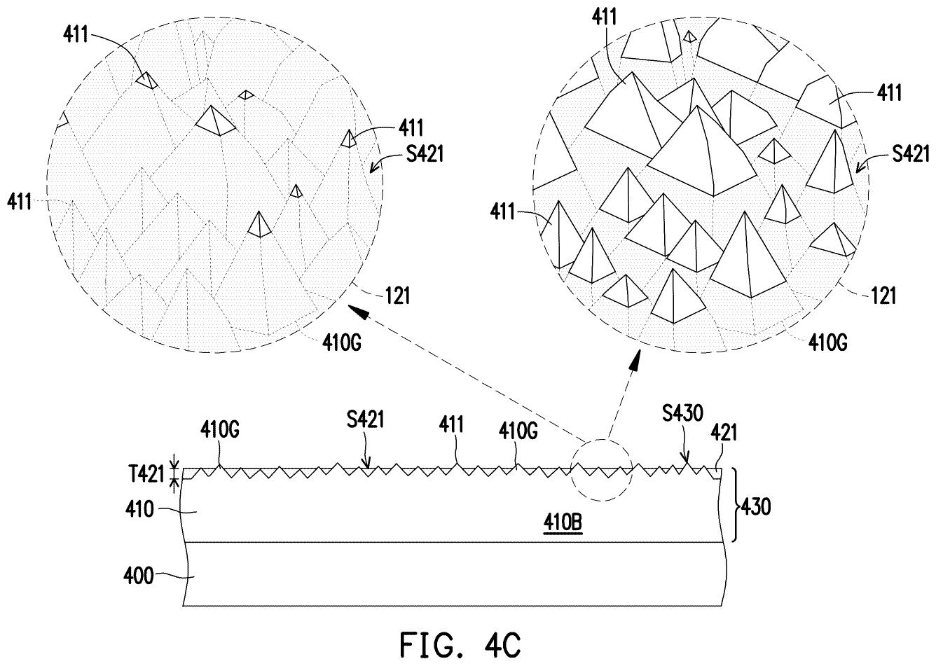

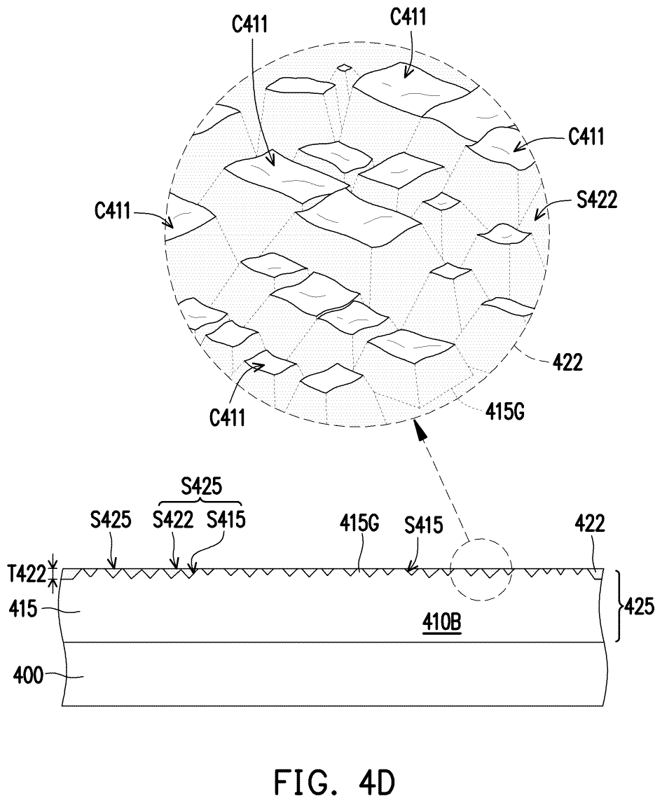

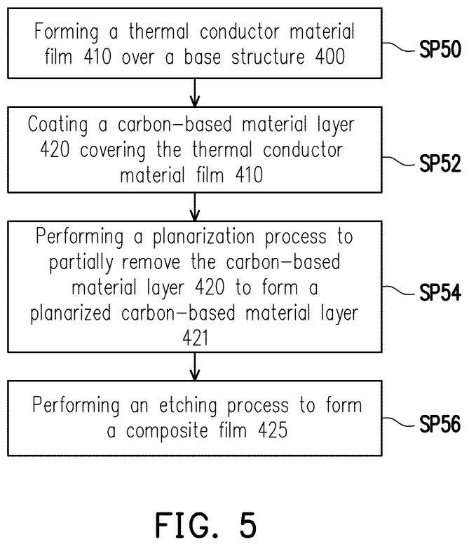

FIGS. 4A-4D are schematic cross-sectional views showing various stages of a manufacturing method for forming a thermal conductor material film over a base structure according to some embodiments of the present disclosure. FIG. 5 is a process flow diagram showing the process steps of the manufacturing method for forming a thermal conductor material film over a base structure according to some embodiments of the present disclosure.

Referring to FIG. 4A and FIG. 5, in Step SP50, a thermal conductor material film 410 is formed over a base structure 400. It is understood that the similar layers, elements or parts or the same or similar structure configuration(s) may be labeled with similar or the same reference labels in the drawings. Herein, the base structure 400 and the thermal conductor material film 410 are respectively similar or substantially the same as the base structure 100 and the thermal conductor material film 110 as described in the previous paragraphs by using the same or similar materials and formation methods, and certain detailed descriptions may be skipped for simplicity.

Referring to FIG. 4A and FIG. 5, in Step SP50, the thermal conductor material film 410 is formed as a homogenous and continuous film covering the base structure 400. In some embodiments, the thermal conductor material film 410 is or includes a film of a high thermal conductivity material, above 100 W/(m·K) at room temperature(s), such as diamond. Referring to FIG. 4A, in some embodiments, the thermal conductor material film 410 (e.g. a diamond film) is formed of nanometric grains (and aggregates) of diamond and has a non-smooth gritty surface (top surface) S410 opposite to the bottom surface B410 (the surface facing and in contact with the base structure 400). For example, through CVD, the deposited crystalline diamond film has a non-smooth and uneven surface formed of faceted micro- or nano-metric grains. In some embodiments, the thermal conductor material film 410 includes a base portion 410B and grainy portions 410G, and the grainy portions 410G form a rugged and faceted surface S410 (illustrated as valleys and peaks or zigzag-shaped in the schematic cross-sectional view) with a surface roughness of R4. In some embodiments, the surface roughness R4 ranges from about 0.1 microns to about 3 microns. For example, the estimation of the surface roughness before or after treatments (such as polishing, etching, and/or deposition) is obtained by profilometry measurements, and values of the arithmetic average roughness (Ra) may be estimated.

Referring to FIG. 4B and FIG. 5, in Step SP52, a carbon-based material layer 420 is formed on the thermal conductor material film 410 fully covering the surface S410 of the thermal conductor material film 410. In some embodiments, the carbon-based material layer 420 is conformally formed over the thermal conductor material film 410. That is, the carbon-based material layer 420 is conformal to the profile of the thermal conductor material film 410 (conformal to the surface topography of the surface S410 of the thermal conductor material film 410). In some embodiments, the carbon-based material layer 420 is formed with a gritty surface S420 conformal to the underlying gritty surface S410 of the thermal conductor material film 410. In some embodiments, the surface S420 has a surface roughness R5 that is substantially equivalent to the surface roughness R4 of the surface S410 of thermal conductor material film 410.

In some embodiments, the carbon-based material layer 420 is formed with a thickness of T420. In some embodiments, the carbon-based material layer 420 may be formed by deposition such as CVD including plasma-enhanced CVD (PECVD), electron cyclotron resonance (ECR) plasma CVD, plasma-based ion implantation and deposition, or physical vapor deposition (PVD) including ionized evaporation, sputtering, ECR sputtering, ion-beam deposition (IBD), pulsed laser deposition (PLD), and laser arc deposition.

In some embodiments, the material of the carbon-based material layer 420 is or includes one or more diamond-like carbon (DLC) materials. DLC materials are amorphous carbon materials having both the σ bonds and π bonds (due to sp3 and sp2 hybrid orbitals constituting diamond and graphite respectively) in the carbon skeletons. In some embodiments, the DLC material used for the carbon-based material layer 420 includes more graphitic sp2 carbons (sp2 bond type as the predominant type), with sp2 fraction (the fraction of sp2 bonded carbon atoms) larger than (or equal to) sp3 fraction (the fraction of sp3 bonded carbon atoms). In some embodiments, DLC materials are hydrogenated DLC materials or fluorinated DLC materials with low dielectric constants. As the bond types considerably influence the properties of the amorphous carbon films, for the DLC materials with the predominant sp2 bond type, the film is softer (softer than crystalline diamond). In some embodiments, the carbon-based material layer 420 has a hardness smaller (i.e. softer) than that of the thermal conductor material film 410. In some embodiments, the DLC materials include other atoms fluorine (F), chlorine (Cl), H, O or N in varying ratios. The material(s) of the carbon-based material layer 420 has a low-dielectric constant (low-K) and provides good thermal conductivity and satisfactory surface adhesion capability.

Referring to FIG. 4C and FIG. 5, in Step SP54, a planarization process is performed to partially remove the carbon-based material layer 420 to become the planarized carbon-based material layer 421. In some embodiments, the planarization process includes a chemical mechanical polishing (CMP) process using the suitable polishing pad and abrasives to selectively remove the material of the carbon-based material layer 420 without removing or minimally removing the thermal conductor material film 410. In some embodiments, the CMP process is performed using a polishing pad with a Shore D hardness larger than 50 and a down force larger than 2 psi for a high throughput process to remove the carbon-based material (e.g. the diamond-like carbon materials). In FIG. 4C, during the planarization process, the carbon-based material layer 420 is partially removed to become the planarized carbon-based material layer 421 with a planarized surface S421 and is polished downward to a reduced thickness T421. In some embodiments, as seen in FIG. 4C, the planarized surface S421 is a smooth (i.e. small surface roughness) and flat surface. Herein, T421 is smaller than T420, and T421 may range from less than two thirds of T420 to half of T420. In some embodiments, the CMP process is performed to remove the carbon-based material layer 420 until the underlying gritty surface S410 is slightly revealed or partially revealed. Herein, such planarization process is similar to the previously described first planarization process, and may be a high throughput planarization process. For example, when the thermal conductor material film 410 is made of crystalline diamond of very high hardness, such planarization process is unlikely to remove the thermal conductor material film 410 but easily removes the softer carbon-based material of the carbon-based material layer 420.

In some embodiments, the CMP process is performed to reveal a minimum or the least of the grainy portions 410G of the thermal conductor material film 410 (i.e. the gritty surface S410 is slightly exposed) by real-time monitoring the changes in the surface roughness. For example, the surface S420 of as-deposited carbon-based material layer 420 has a surface roughness R5, through the planarization process, the surface S420 becomes smoother and flatter, the surface roughness keeps decreasing, and the planarization process is well controlled to stop when the monitored surface roughness reaches a desirable value.

As seen at upper left part of FIG. 4C, a schematic partial enlarged view of the surface topography of the underlying thermal conductor material film 410 mostly covered but slightly exposed from the planarized surface S421 after the planarization process is shown. In the schematic partial enlarged view of FIG. 4C, the small and large pyramids representing the facets of the diamond crystals or grains (e.g. grainy portions 410G) of the underlying thermal conductor material film 410, it is seen that most of the peak portions (sharp points or tips) 411 are covered by the planarized carbon-based material layer 421 and few peak portions 411 are protruded out of and exposed from the polished surface S421.

Following the process steps SP50-SP54, after performing the planarization process, a composite film 430 that consists of the thermal conductor material film 410 and the planarized carbon-based material layer 421 is obtained with a surface S430, and the surface S430 of the obtained composite film 430 has a surface roughness R6 (average surface roughness). In some embodiments, the end point of the planarization process is well controlled to balance the removal of the carbon-based material layer 420 and the exposure of the gritty surface S410 so as to attain the desirable surface roughness that is favorable and satisfactory depending on the processing requirements. In some embodiments, the surface roughness R6 of the composite film 430 is reduced by at least one third or more of the surface roughness R4 of the untreated thermal conductor material film 410. In some embodiments, the surface roughness R6 is decreased to about half of the surface roughness R4, or decreased to about one third (or lower) of the surface roughness R4 of the untreated thermal conductor material film 410. In some embodiments, the surface roughness R6 is about or less than about 1 micron. In some embodiments, the surface roughness R6 is about or less than 200 nm. In some embodiments, the surface roughness R6 is about or less than 10 nm.

In some embodiments, for the composite film 430, the planarized carbon-based material layer 421 fills in the cavities (or valleys) between the sporadically distributed grains (e.g. grainy portions 410G) of the thermal conductor material film 410. That is, in the composite film 430 consisting of the thermal conductor material film 410 and the planarized carbon-based material layer 421, the peak portions 411 are surrounded by the planarized carbon-based material layer 421 and few are exposed from the planarized carbon-based material layer 421 to reach a satisfactory surface roughness.

As seen at upper right part of FIG. 4C, a schematic partial enlarged view of the surface topography of the underlying thermal conductor material film 410 exposed from the polished surface S421 after the planarization process is shown. In the schematic partial enlarged view of FIG. 4C, it is seen that most of the peak portions (sharp points or tips) 411 of the grains (grainy portions 410G) in the thermal conductor material film 410 are protruded out of and exposed from the polished surface S421 of the planarized carbon-based material layer 421.

Referring to FIG. 4D and FIG. 5, in Step SP56, an etching process (i.e. an etch-back process) is performed to etch the composite film 430, etching the thermal conductor material film 410 into the etched thermal conductor material film 415 and etching the planarized carbon-based material layer 421 into the etched carbon-based material layer 422 so as to form a composite film 425. In some embodiments, the etching process includes performing a plasma etching process using oxygen containing plasma such as oxygen (O2) plasma or ozone (O3) plasma. In some embodiments, the etching process uses etchants including fluorine-containing compounds. In Step SP56, during the etching process performed to the composite film 430, both of the thermal conductor material and the carbon-based material are etched and removed. Referring to FIG. 4C and FIG. 4D, the planarized carbon-based material layer 421 is thinned down by the etching process and becomes the etched carbon-based material layer 422 with an etched surface S422 and of a reduced thickness T422 (T422<T421), and the peak portions 411 of the grainy portions 410G of the thermal conductor material film 410 are also etched during the etching process so that the grainy thermal conductor material film 410 is etched to become the etched thermal conductor material film 415 with the etched surface S415 that is less gritty than the gritty surface S410.

In some embodiments, Step SP56 may be omitted, if the composite film 430 is preferred, and the satisfactory surface roughness is reached.

In some embodiments, the etching process may have different etching rates toward the materials of the thermal conductor material film 410 and of the carbon-based material layer 420. In some embodiments, the etching process shows a higher etching rate toward the thermal conductor material film 410 and a lower etching rate toward the carbon-based material layer 420 (or the layer 421). In some embodiments, the etching process performed shows a higher etching rate for crystalline diamond, relative to the etching rate for the DLC material(s). However, since carbon exists in both of the diamond and DLC materials, the differences in the etching rates for both materials may not be large, such etching process is less selective or non-selective, when compared with the previously described selective etching process. In some embodiments, the end point of the etching process may be determined by monitoring the surface roughness in real-time and/or in a time-control mode.

As seen at upper right part of FIG. 4D, a schematic partial enlarged view of the surface topography of the etched thermal conductor material film 415 exposed from the etched surface S422 after the treatment of the etching process is shown, it is seen that etched surfaces C411 of the grains (depicted as truncated pyramids) are revealed and certain mesa portions 415G are protruded from the etched surface S422 as the peak portions 411 (in FIG. 4C) of the grainy portions 410G in the thermal conductor material film 410 are etched off during the etching process. In some embodiments, through the etching process, the grainy thermal conductor material film 410 becomes the etched thermal conductor material film 415, as the grainy portions 410G of the thermal conductor material film 410 are flattened and become mesa portions 415G located above the base portion 410B of the etched thermal conductor material film 415.

In some embodiments, the etching process is well-controlled for obtaining the minimum of the surface roughness, the etched surfaces C411 are flush with and joined with the surface S422 to form a joined surface S425. In some embodiments, the composite surface S425 is a diamond containing surface. In some embodiments, the plasma etching process may be isotropic etching, and the etched surfaces C411 or the etched surface S422 are smoothly curved surfaces. In some embodiments, the plasma etching process may be anisotropic etching, and the etched surface C411 and the etched surface S422 are substantially flat surfaces.

After performing the etching process and following the process steps SP50-SP56, a composite film 425 that consists of the etched thermal conductor material film 415 and the etched carbon-based material layer 422 is obtained with a surface S425, and the surface S425 of the obtained composite film 425 has a surface roughness R7 (average surface roughness). In some embodiments, the end point of the etching process is well controlled so as to attain the desirable surface roughness that is favorable and satisfactory depending on the processing requirements. In some embodiments, the surface roughness R7 of the composite film 425 is reduced by at least one third or more of the surface roughness R4 of the untreated thermal conductor material film 410. In some embodiments, the surface roughness R7 is about half of the surface roughness R4, or about one third (or lower) of the surface roughness R4 of the untreated thermal conductor material film 410. In some embodiments, the surface roughness R7 is about or less than about 1 micron. In some embodiments, the surface roughness R7 is about or less than 200 nm. In some embodiments, the surface roughness R7 is about or less than 10 nm.

In some embodiments, for the composite film 425, the etched carbon-based material layer 422 fills in the cavities (or valleys) between the sporadically distributed grains (e.g. mesa portions 415G) of the etched thermal conductor material film 415. From a top view, in the composite film 425 consisting of the thermal conductor material film 415 and the carbon-based material layer 422, the mesa portions 415G of the etched thermal conductor material film 415 are exposed or even protruded from the surrounding carbon-based material layer 422 while the surface S425 offers a satisfactory surface roughness.

For the previously described composite films, the films provide good thermal conductivity and satisfactorily low surface roughness. Especially, the thermal conductor material (such as diamond) exposed from the surface of the composite film(s) can assist heat transfer efficiently and function as heat spreader, while the carbon-based material layer can increase the adhesion of the composite surface and enhance the bonding adhesion between the composite surface (e.g. diamond containing surface) of the composite film and other surfaces of the adjacent layers or components.

Following the process steps SP50-54 or SP50-SP56, the composite film 430 or 425 is obtained with a less gritty and smoother surface with a low surface roughness. By doing so, a high-quality composite film is formed, and the surface roughness of the thermal conductor material film becomes lower (smaller). Though the previously described process steps, it is possible to form high quality thermal conductor material film (e.g. diamond film) with better planarity and smoothness under processing conditions compatible with backend of line (BEOL) processes without using high temperature conditions or sintering techniques. By doing so, the thermal conductor material film of high thermally conductivity may be incorporated within the BEOL structures and package structures.

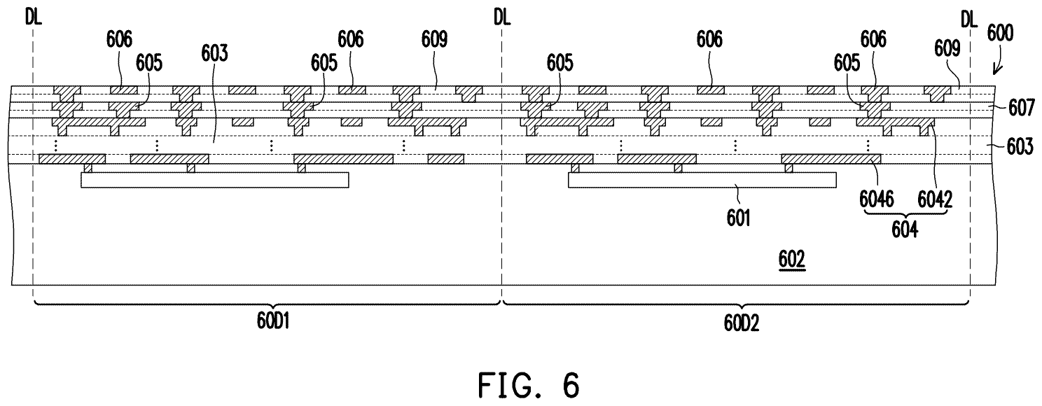

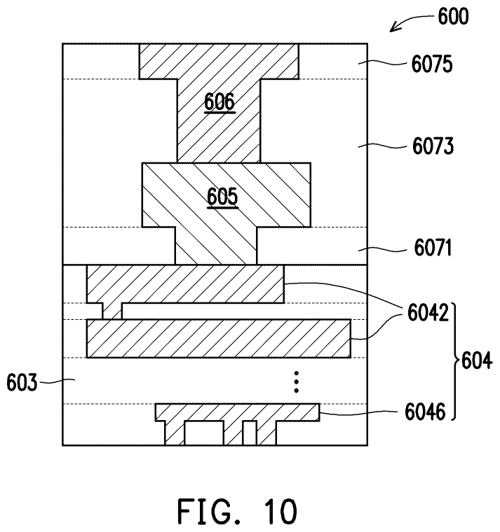

FIGS. 6-8 are schematic cross-sectional views showing various stages of a manufacturing method for forming a stacking structure according to some embodiments of the present disclosure. FIG. 10 is an enlarged cross-sectional view showing a bonding portion relative to the underneath element(s) within the stacking structure according to some embodiments of the present disclosure.

In FIG. 6, in some embodiments, a wafer 600 is provided, and the wafer 600 may be similar to or as a part of the base structure 100 described in previous paragraph(s). In some embodiments, the wafer 600 is a semiconductor wafer including a semiconductor substrate 602 with a device layer 601, metallization structures 604 formed over the semiconductor substrate 602 and the device layer 601, metallic contacts 605 and bonding structures 606 formed on the metallization structures 604 and over the semiconductor substrate 602. In some embodiments, the wafer 600 is a silicon wafer, or a bulk wafer made of other semiconductor materials such as III-V semiconductor materials such as gallium nitride (GaN) or gallium arsenide (GaAs). In some embodiments, the substrate 602 may be a monocrystalline semiconductor substrate such as a silicon substrate, a silicon-on-insulator (SOI) substrate, silicon-germanium on insulator (SGOI) or a germanium-on-insulator (GOI) substrate. In certain embodiments, the device layer 601 includes semiconductor devices formed in or on the semiconductor substrate 602 of the wafer 600 during the front-end-of-line (FEOL) processes. In certain embodiments, the semiconductor devices are active devices or include transistors, memories or power devices. In certain embodiments, the semiconductor devices are or include capacitors, resistors, diodes, photo-diodes, sensors, inductors or fuses. In exemplary embodiments, some of the semiconductor devices are electrically connected with the metallization structures 604, and some of the semiconductor devices are electrically inter-connected with one another through the metallization structures 604.

In some embodiments, referring to FIG. 6, the wafer 600 includes a plurality of die units or semiconductor dies before dicing or singulation. In FIG. 6, a portion of the wafer 600 including at least two die units 60D1 and 60D2 are shown and defined by the dicing lanes DL (in dashed lines). It is understood that the number of the die units or semiconductor dies is merely exemplary and more than two dies are included. In some embodiments, the die units (or semiconductor dies) 60D1 and 60D2 are or include different types of dies with different functions. In some embodiments, the die units (or semiconductor dies) 60D1 and 60D2 are or include the same type of dies or dies of the same functions.

As shown in FIG. 6, in certain embodiments, the metallization structures 604 are embedded within a dielectric material 603 formed on the semiconductor substrate 602. In some embodiments, the metallization structures 604 include multiple metallization layers of interconnect structures, including interconnected metal lines, vias and contact pads (certain detailed configurations and interlayers are omitted and represented by the ellipsis dots). In some embodiments, the metallization structures 604 at least include top metallization layer(s) 6042 and bottom metallization layer(s) 6046 that are electrically connected, and the bottom metallization layer 6046 is electrically connected to the device layer 601. In some embodiments, the metallic contacts 605 including metallic pads are embedded in a dielectric layer 607 and are located on and connected to the top metallization layer(s) 6042. In some embodiments, the bonding structures 606 including metallic bonding pads are embedded in a dielectric layer 609 and are located on the metallic contacts 605 above the metallization structures 604. In FIG. 6, in some embodiments, some of the bonding structures 606 are directly connected to the metallic contacts 605, and the bonding structures 606 are electrically connected with the device layer 601 through the metallic contacts 605 and the metallization structures 604. In exemplary embodiments, the wafer 600 may include through semiconductor vias (TSVs) for further electrical connection.

Herein, the metallization structures 604, the metallic contact 605 and the bonding structures 606 shown herein are merely for illustrative purposes, and the metallization structures 604, the metallic contact 605 and the bonding structures 606 may include other configurations and may include one or more through vias and/or damascene structures. The disclosure does not limit the number of layers of the metallization structures, and the number of the metallization layers illustrated in the drawings is merely exemplary. Additional layers such as seed layers and barrier layers may also be formed along with the metallization structures, metallic contact and/or the bonding structures.

In certain embodiments, the materials of the metallization structures 604, the metallic contact 605 and the bonding structures 606 include aluminum (Al), aluminum alloys, copper (Cu), copper alloys, titanium (Ti), tantalum (Ta), cobalt (Co), nickel (Ni), tungsten (W), nitrides thereof, or combinations thereof. In some embodiments, the metallic contacts 605 include aluminum pads, copper pads or copper alloy pads. In some embodiments, the top and bottom metallization layers 6042, 6046 and metallic layers formed in-between are formed from the same metallization processes and are made of the same metal materials. In some embodiments, the top and bottom metallization layers 6042, 6046 are made of copper or copper alloys. In some embodiments, the bonding structures 606 include bonding pads of copper or copper alloys. The formation of the metal or metallic layer involves plating (such as electrochemical plating), deposition or other suitable process.

In some embodiments, the materials of the dielectric material 605 and the dielectric layers 607, 609 include silicon oxide, silicon nitride, spin-on dielectric materials, low-k dielectric materials or a combination thereof. In some embodiments, the insulative dielectric material 605 includes one or more low-k dielectric layers. Examples of low-k dielectric materials include undoped silicate glass (USG), borophosporosilicate glass (BPSG), phosporosilicate glass (PSG), hydrogen silsesquioxane (HSQ), fluorinated silicon oxide (SiOF), Xerogel, Aerogel, amorphous fluorinated carbon, or polymeric materials including parylene, BCB (bis-benzocyclobutenes), polyimide, flare, and/or a combination thereof.

In some embodiments, the formation of the dielectric layer 607 includes performing process steps SP20-SP28 as described in the previous paragraphs, and the dielectric layer 607 includes at least one thermal conductor material film similar to or the same as the aforementioned thermal conductor material film 115. In some embodiments, the formation of the dielectric layer 607 includes performing process steps SP20-SP26 as described in the previous paragraphs, and the dielectric layer 607 includes at least one composite thermal conductor material film similar to or the same as the aforementioned composite film 125. In some embodiments, the formation of the dielectric layer 607 includes performing process steps SP50-SP56 as described in the previous paragraphs, and the dielectric layer 607 includes at least one thermal conductor material film similar to or the same as the aforementioned composite thermal conductor material film 425. In some embodiments, the formation of the dielectric layer 607 includes performing process steps SP50-SP54 as described in the previous paragraphs, and the dielectric layer 607 includes at least one thermal conductor material film similar to or the same as the aforementioned composite thermal conductor material film 430.

In some embodiments, the formation of the dielectric layer 609 includes performing process steps SP20-SP28 as described in the previous paragraphs, and the dielectric layer 609 includes at least one thermal conductor material film similar to or the same as the aforementioned thermal conductor material film 115. In some embodiments, the formation of the dielectric layer 609 includes performing process steps SP20-SP26 as described in the previous paragraphs, and the dielectric layer 609 includes at least one composite thermal conductor material film similar to or the same as the aforementioned composite film 125. In some embodiments, the formation of the dielectric layer 609 includes performing process steps SP50-SP56 as described in the previous paragraphs, and the dielectric layer 609 includes at least one thermal conductor material film similar to or the same as the aforementioned composite thermal conductor material film 425. In some embodiments, the formation of the dielectric layer 609 includes performing process steps SP50-SP54 as described in the previous paragraphs, and the dielectric layer 609 includes at least one thermal conductor material film similar to or the same as the aforementioned composite thermal conductor material film 430.

Through the incorporation of the thermal conductor material film or the composite thermal conductor material film, heat generated from the below device layer or from other hot spots may be efficiently transferred and dissipated. By way of forming the thermal conductor material film around or adjacent to the bonding structures (adjacent to the bonding interface), the thermal dissipation efficiency is significantly improved for the stacking layers around the bonding structures and the thermal resistance for the bonding interface is greatly lowered.

The disclosure does not limit the number of layers of the dielectric material 605 and the dielectric layers 607 and 609, and the number of sublayers included in the dielectric material 605, the dielectric layers 607, 609, and the number of the layers or sublayers illustrated in the drawings is merely exemplary. Additional layers such as lining layers, adhesion layers or etch stop layers may also be formed in between the layers or sublayers thereof.

For illustration purposes, portions of the metallic contact and bonding structures and the dielectric layers surrounding the metallic contact and bonding structures are illustrated in the schematic enlarged views of FIG. 10 to show the exemplary configurations with more details. Referring to the bonding portion of the wafer 600 shown in FIG. 10, in some embodiments, the metallic contact(s) 605 and the bonding structure(s) 606 are embedded in dielectric stacking layers including sublayers 6071, 6073 and 6075 formed over the dielectric material 605 and the metallization structures 604. In some embodiments, the metallization structures 604 are electrically connected with the above metallic contact(s) 605 and the bonding structure(s) 606. The formation of the dielectric stacking layers including sublayers 6071, 6073 and 6075 will be described in further details in the subsequent paragraphs.

Referring to FIG. 10, in some embodiments, the sublayer 6071 is formed on the dielectric material 605 covering the metallization structures 604 and over the substrate 602. As described in the aforementioned paragraphs, the sublayer 6071 may be formed following the process steps SP20-28 and using the same material(s) for forming the film 115, the sublayer 6071 is formed as a thermal conductor material film similar to the film 115. In some embodiments, the sublayer 6071 is or includes a film of a high thermal conductivity material (above 100 W/(m·K) at room temperatures) with a surface roughness less than 1.5 microns or about or even less than 50 nm. In some embodiments, the sublayer 6071 is or includes a crystalline diamond film with a satisfactory surface roughness. Later, metallic contact(s) 605 is formed in the opening(s) of the sublayer 6071 through metallization formation and patterning processes.

In some embodiments, the sublayer 6073 is formed over the sublayer 6071 and covering the metallic contact(s) 605. As described in the aforementioned paragraphs, the sublayer 6073 may be formed following the process steps SP50-54 and using the same material(s) for forming the film 430, the sublayer 6073 is formed as a composite thermal conductor material film similar to the film 430. In some embodiments, the sublayer 6073 is or includes a composite film of a high thermal conductivity material (above 100 W/(m·K) at room temperatures) and a carbon-based material, with a composite surface having a surface roughness less than 1.5 microns or about or even less than 50 nm. In some embodiments, the sublayer 6073 is or includes a composite film of crystalline diamond and a diamond-like carbon material film with a satisfactory surface roughness.

In some embodiments, the sublayer 6075 is formed over the sublayer 6073. As described in the aforementioned paragraphs, the sublayer 6075 may be formed following the process steps SP20-26 and using the same material(s) for forming the film 125, the sublayer 6075 is formed as a composite thermal conductor material film similar to the film 125. In some embodiments, the sublayer 6075 is or includes a composite film of a high thermal conductivity material (above 100 W/(m·K) at room temperatures) and a spin-on dielectric material, with a composite surface having a surface roughness less than 1.5 microns or about or even less than 50 nm. In some embodiments, the sublayer 6075 is or includes a composite film of crystalline diamond and a silicon-based dielectric material with atoms O, C, or N in varying ratios with a satisfactory surface roughness.

In some embodiments, at least one of the sublayers 6071, 6073 and 6075 is or includes a thermal conductor material film or a composite thermal conductor material film, and it is possible that two or all of the sublayers 6071, 6073 and 6075 each is or includes a thermal conductor material film or a composite thermal conductor material film. The sublayers described herein are merely exemplary and for illustration purposes, and it is possible to switch either sublayer with the other sublayer(s).

In some embodiments, by incorporating a thermal conductor material film or a composite thermal conductor material film in the stacking dielectric layers surrounding the metallic contacts and/or the bonding structures, satisfactory thermal dissipation efficiency can be achieved for the semiconductor stacking structure or packaging structure. Further, for the composite thermal conductor material film offering a very low surface roughness, the thermal conductor material (such as diamond) exposed from the surface of the composite film can assist heat transfer efficiently and function as heat spreader, while the remained spin-on dielectric material or carbon-based material can assist the adhesion of the composite surface and enhance the bonding between the composite surface (e.g. diamond containing surface) of the composite film and other surfaces of the adjacent layers or components.

Later, through the formation of the dual damascene opening(s) in the sublayers 6073 and 6075, the bonding structure(s) 606 is formed in the opening of the sublayers 6073 and 6075 and connected to the metallic contact(s) 605. It is understood that the openings may be formed through suitable formation process(es) for forming trenches, damascenes, via openings or other openings with suitable configurations, and the dual damascene processing described herein is merely exemplary.

In some embodiments, the sublayers 6071, 6073, 6075 may be formed to further include other dielectric sublayers of silicon oxide, silicon nitride, silicon oxynitride (SiON), silicon carbonitride (SiCN) or other oxide-based low-k dielectric materials. In some embodiments, the individual sublayers may be fabricated to a suitable thickness by CVD such as flowable CVD, PECVD, SACVD, spin-coating, sputtering, or other suitable methods.

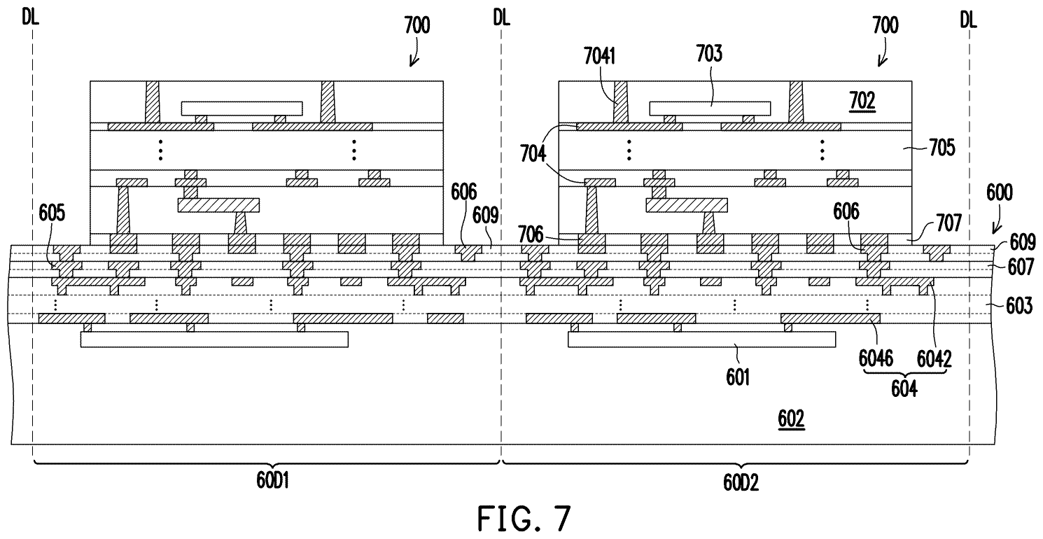

Referring to FIG. 7, multiple dies 700 (only two are shown) are provided, disposed side-by-side, and stacked onto the wafer 600. In certain embodiments, each die 700 includes a semiconductor substrate 702, a device layer 703, metallization structures 704 embedded in the insulation material 705 formed over the semiconductor substrate 702 and bonding structures 706 disposed on and electrically connected to the metallization structures 704 (from top to bottom as the die 700 faces down). In embodiments, each die 700 includes semiconductor devices formed in the device layer 703 and isolation structures (not shown) formed in the semiconductor substrate 702. In certain embodiments, the metallization structures 704 include through semiconductor vias (TSVs) 7041 and interconnected metal lines and vias (certain detailed configurations and interlayers are omitted and represented by the ellipsis dots). In some embodiments, the bonding structures 706 include bonding pads embedded in a dielectric material layer 707.

During the placement of the dies 700, the dies 700 are arranged to align the bonding structures 706 with the corresponding bonding structures 606 of the wafer 600 respectively, so that the bonding pads of the respective bonding structures 606, 706 are substantially vertically aligned (along the stacking direction). Then, in some embodiments, as shown in FIG. 7, a bonding process is performed to bond the bonding structures 606 and 706 so as to bond the dies 700 onto the wafer 600. In some embodiments, the bonding process includes performing a low temperature heating process at a temperature of about 150 degrees Celsius to about 250 degrees Celsius to bond the dielectric materials of the layer 707, 609 (dielectric-to-dielectric bonding) and the metallic bonding pads of the bonding structures 706, 606 (metallic-to-metallic bonding). In some embodiments, the dies 700 are bonded to the wafer 600 through hybrid interfacial bonding to form a die-stacked-on-wafer structure.

In some embodiments, as seen in FIG. 7, the bonding structures 706 of the dies 700 are bonded with the bonding structures 606 of the wafer 600. In some embodiments, some of the bonding pads of the bonding structures 706 are bonded and electrically connected with the bonding pads of the bonding structures 606 of the wafer 600 so that the semiconductor devices in the device layer 601 are electrically connected with the semiconductor devices in the device layer 703 through the bonding structures 706, 606 and the metallization structures 704, 604.

In some embodiments, among the dies 700, there are the same dies of the same function or the same size, or there are different dies performing different functions or of different sizes. In some embodiments, the dies 700 include logic dies, such as central processing unit (CPU) dies, graphic processing unit (GPU) dies, micro control unit (MCU) dies, baseband (BB) dies, or application processor (AP) dies, or memory dies, such as high bandwidth memory (HBM) dies, dynamic random access memory (DRAM) dies, or static random access memory (SRAM) dies. In some embodiments, the dies 700 include application-specific integrated circuit (ASIC) dies, analog dies, sensor dies, wireless application dies (including Bluetooth chips and/or radio frequency chips) or voltage regulator dies.

In some embodiments, the dies 700 are semiconductor dies fabricated from a semiconductor wafer with similar configuration design as shown for the die unit(s) of the wafer structure 100 or wafer 100A. In certain embodiments, the materials of the metallization structures 704 may be similar to or the same as that of the metallization structures 604. In certain embodiments, the materials of the dielectric material layer 707 may be similar to or the same as those of the dielectric layers 607, 609. In some embodiments, it is possible to incorporate a thermal conductor material film or a composite thermal conductor material film in the dielectric material layer 707.

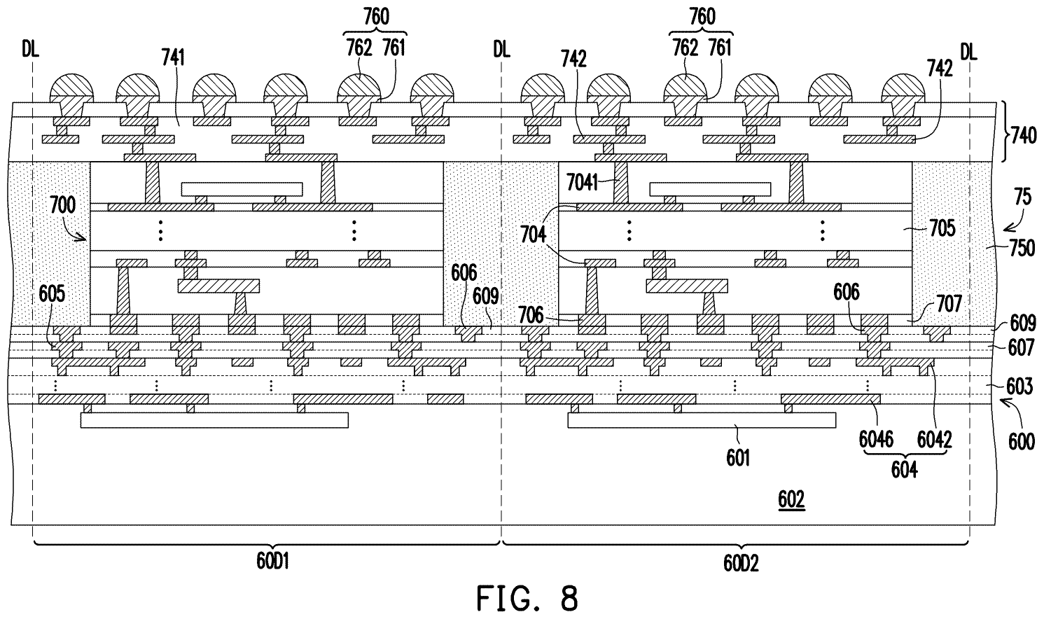

Referring to FIG. 8, after stacking and bonding dies 700 onto the wafer 600, a filling material 750 is formed over the die-stacked-on-wafer structure, especially filling the gaps between the dies 700 on the wafer 600 to form a molded structure 75. In some embodiments, the filling material 750 is an insulating material. In one embodiment, the filling material 750 is formed by chemical vapor deposition (CVD), spin coating or molding. In some embodiments, the material of the filling material 750 includes silicon oxide, silicon nitride, epoxy resins, phenolic resins or silicone resins. In some embodiments, the filling material 750 at least covers the top surface of the wafer 600, fills the gaps between the dies 700 and covers the sidewalls of the dies 700. In some embodiments, a planarization process may be performed to partially remove the filling material 750 as well as portions of the dies 700, and after planarization, the backsides of the dies 700 are polished and the TSVs 7041 are exposed. In some embodiments, the planarized filling material 750 fully and laterally covers the sidewalls of the dies 700 bonded onto the wafer 600.

By way of forming the thermal conductor material film around or adjacent to the bonding structures (adjacent to the bonding interface), the thermal dissipation efficiency is significantly improved for the stacking layers around the bonding structures and the thermal resistance for the bonding interface is greatly lowered. Furthermore, by incorporating the thermal conductor material film or the composite thermal conductor material film into the layer surrounding the bonding structures, high-quality bonding is established for the semiconductor stacking structure fabricated from die-on-wafer processes or wafer-on-wafer processes. Also, stronger bonding is achieved between the composite thermal conductor material film and the dielectric material of die(s) of the semiconductor stacking structures such as multiple die stacked structures, system integrated chips or 3D integrated chiplets.

Referring to FIG. 8, in some embodiments, a redistribution layer (RDL) 740 is formed over the molded structure 300 and is formed on the filling material 750 and on the second dies 75. The redistribution layer (RDL) 740 is electrically connected to the dies 700 through at least the TSVs 7041. In some embodiments, the RDL 740 includes redistribution metal patterns 742 embedded in a dielectric material layer 741. The configuration of the redistribution metal patterns is not limited by the disclosure, while the dielectric material layer may include more than one layers of dielectric materials. In certain embodiments, conductive terminals 760 are formed on the exposed metal patterns 742. In some embodiments, the conductive terminal 760 includes a metal post 761 and a bump 762. In some embodiments, a material of the metal post 761 includes copper or cooper alloys, and a material of the bump 762 includes solder. In one embodiment, the metal posts 761 and bumps 762 located on the metal posts 761 constitute micro bumps. In some embodiments, the conductive terminals 760 include copper pillar bumps.

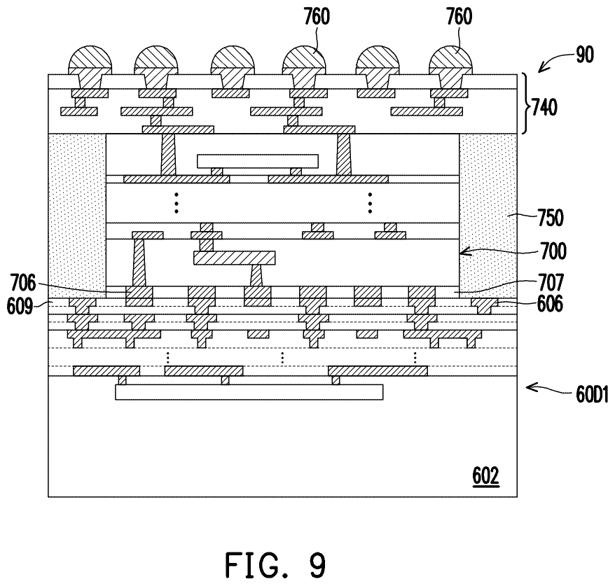

Later, in some embodiments, referring to FIG. 8 and FIG. 9, a singulation process is performed to cut the molded structure 75 and cutting through the RDL 740 along the dicing lanes DL into individual three-dimensional (3D) stacking structures 90. In some embodiments, the singulation process includes a wafer dicing process or a sawing process. In exemplary embodiments, in reference to the exemplary arrangement having at least one second die 700 included within one die unit (defined by the dicing lanes DL) as shown in FIG. 9, after singulation, each of the singulated 3D stacking structures 90 includes at least one second die 700 stacked on the semiconductor die 60D1 (or 60D2) and the filling material 750 laterally wrapping around the second die 700. In some embodiments, the as-described thermal conductor material film or the composite thermal conductor material film is incorporated in the dielectric layers 607, 609 adjacent to the bonding structures 606 or incorporated in the dielectric material layer 707 arranged adjacent to the bonding structures 706. Through such arrangements, better thermal dissipation efficiency is achieved for the stacking structures near the bonding interface. The existence of the thermal conductor material film or the composite thermal conductor material film of high thermal transfer capability establish good thermal conductive paths between the bonded semiconductor dies 60D1 (or 60D2) and 700 of the 3D stacking structure 90.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure. Furthermore, whilst the illustrated processes belong to a chip-on-wafer (CoW) process and may be further fabricated into 3D stacking packages or chip-on-wafer-on-substrate (CoWoS) packages.

In some embodiments, through the thermal conductor material film or the composite thermal conductor material film arranged adjacent to the bonding structures 606, 706, good thermal conductive paths are established between the semiconductor dies 60D1 (or 60D2), 700 of the 3D stacking structure 90. For the obtained 3D stacking structure 90, better bonding is established between the dies 60D1/60D2 and 700 by way of smoothness and planarity provided by the thermal conductor material film of a small surface roughness and better adhesion provided by the composite thermal conductor material film, and better reliability and satisfactory electrical performance are offered.

According to the embodiments of this disclosure, the formation of the thermal conductor material film or the composite thermal conductor material film around, adjacent or even below the bonding pads lowers the thermal barrier at bonding interfaces and enhances the bonding strength.

In some embodiments of the present disclosure, a fabrication method is provided. After providing a base structure, a thermal conductor material film is formed on the base structure. The thermal conductor material film is formed with a gritty surface with a first surface roughness. A material layer is formed on the thermal conductor material layer covering the gritty surface. The material layer has a hardness smaller than that of the thermal conductor material film. The material layer includes a flattening dielectric layer or a carbon-based material layer. A first planarization process is performed to partially remove the material layer to form a planarized material layer with a planarized surface, and portions of the thermal conductor material film are partially exposed from the planarized surface. An etching process is performed to etch the thermal conductor material film by removing the exposed portions of the thermal conductor material film to form a composite thermal conductor material film with a second surface roughness. The composite thermal conductor material film includes the etched thermal conductor material film and the remained planarized material layer, and the second surface roughness is reduced by about half of the first surface roughness.

In some embodiments of the present disclosure, a stacking structure including a first and a second die stacked on the first die is disclosed. The first die includes a first substrate, a first dielectric layer located over the first substrate, and a first bonding structure located in the first dielectric layer and over the first substrate. The first dielectric layer includes a composite thermal conductor material film, and the composite thermal conductor material film has a diamond containing surface. The second die includes a second substrate, a second dielectric layer located over the second substrate, and a second bonding structure located in the second dielectric layer and over the second substrate. The first and second dies are bonded through the bonded first and second dielectric layers and the bonded first and second bonding structures.

In some embodiments of the present disclosure, a method for forming stacking structures is described. A first structure having a first substrate and a second structure having a second substrate are provided. A first dielectric layer is formed over the first substrate and first bonding structures are formed in the first dielectric layer. The first dielectric layer is formed to include a composite thermal conductor material film having a diamond containing surface. A second dielectric layer is formed over the second substrate and second bonding structures are formed in the second dielectric layer. The second bonding structures are aligned with the first bonding structures. The first structure is bonded with the second structure by bonding the first and second dielectric layers and bonding the first and second bonding structures. A singulation process is performed to form individual stacking structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A fabrication method, comprising:
providing a base structure;
forming a thermal conductor material film on the base structure, wherein the thermal conductor material film is formed with a gritty surface with a first surface roughness;
forming a material layer on the thermal conductor material layer and covering the gritty surface, wherein the material layer has a hardness smaller than that of the thermal conductor material film, and the material layer includes a flattening dielectric layer or a carbon-based material layer;
performing a first planarization process to partially remove the material layer to form a planarized material layer with a planarized surface, and portions of the thermal conductor material film are partially exposed from the planarized surface; and
performing an etching process to etch the thermal conductor material film by removing the exposed portions of the thermal conductor material film to form a composite thermal conductor material film with a second surface roughness, wherein the composite thermal conductor material film includes the etched thermal conductor material film and the remained planarized material layer, and the second surface roughness is reduced by about half of the first surface roughness.

2. The method of claim 1, wherein the material layer includes a flattening dielectric layer formed from a flowable low-k dielectric material, and the thermal conductor material film includes diamond.

3. The method of claim 2, wherein performing an etching process includes performing a selective etching process to etch the thermal conductor material film without removing the planarized material layer.

4. The method of claim 3, wherein the selective etching process has a higher etching rate to the diamond and has a lower etching rate to the flattening dielectric layer.

5. The method of claim 4, wherein the selective etching process exhibits an etching selectivity from about 10:1 (the diamond: the flattening dielectric layer) to about 100:1 (the diamond: the flattening dielectric layer).

6. The method of claim 2, further comprising performing a second planarization process to remove the remained planarized material layer from the composite thermal conductor material film to expose the etched thermal conductor material film, wherein the exposed surface of the etched thermal conductor material film has a third surface roughness, and the third surface roughness is reduced by at least one third or more of the first surface roughness.

7. The method of claim 1, wherein the material layer includes a carbon-based material layer formed of a diamond-like carbon material, and the thermal conductor material film includes diamond.

8. The method of claim 7, wherein performing an etching process to etch the thermal conductor material film also etches the planarized material layer.

9. The method of claim 8, wherein the etching process has a higher etching rate to the diamond and has a lower etching rate to the carbon-based material layer.

10. A stacking structure, comprising:
a first die, wherein the first die includes a first substrate, a first dielectric layer located over the first substrate, and a first bonding structure located in the first dielectric layer and over the first substrate, wherein the first dielectric layer includes a composite thermal conductor material film, and the composite thermal conductor material film has a diamond containing surface; and
a second die stacked on the first die, wherein the second die includes a second substrate, a second dielectric layer located over the second substrate, and a second bonding structure located in the second dielectric layer and over the second substrate, and
wherein the first and second dies are bonded through the bonded first and second dielectric layers and the bonded first and second bonding structures.

11. The structure of claim 10, wherein the composite thermal conductor material film includes a diamond film and a flattening dielectric layer stacked on the diamond film.

12. The structure of claim 11, wherein portions of the diamond film are exposed from the flattening dielectric layer surrounding the diamond film, and surfaces of the exposed portions of the diamond film are substantially flush with a surface of the flattening dielectric layer to form the diamond containing surface.

13. The structure of claim 10, wherein the composite thermal conductor material film includes a diamond film and a carbon-based material layer stacked on the diamond film.

14. The structure of claim 13, wherein portions of the diamond film are exposed from the carbon-based material layer surrounding the diamond film, and surfaces of the exposed portions of the diamond film are joined with a surface of the carbon-based material layer to form the diamond containing surface.

15. The structure of claim 10, wherein the first dielectric layer includes a first composite thermal conductor material film of a first diamond film and a first flowable low-k dielectric layer stacked on the first diamond film, and the second dielectric layer includes a second composite thermal conductor material film of a second diamond film and a second flowable low-k dielectric stacked on the second diamond film, and a material of the first flowable low-k dielectric layer is different from a material of the second flowable low-k dielectric layer.

16. A method for forming stacking structures, comprising:
providing a first structure having a first substrate, wherein the first structure includes first dies in a wafer form;
forming a first dielectric layer over the first substrate and forming first bonding structures in the first dielectric layer, wherein forming the first dielectric layer includes forming a composite thermal conductor material film having a diamond containing surface;
providing a second structure having a second substrate, wherein the second structure includes second dies in a wafer form;
forming a second dielectric layer over the second substrate and forming second bonding structures in the second dielectric layer;
aligning the second bonding structures with the first bonding structures;
bonding the first structure with the second structure by bonding the first and second dielectric layers and bonding the first and second bonding structures; and
performing a singulation process to form individual stacking structures.

17. The method of claim 16, wherein forming a composite thermal conductor material film includes forming a diamond film and forming a flattening dielectric layer directly on and covering the diamond film.

18. The method of claim 17, further comprising performing a planarization process to planarize the flattening dielectric layer to expose portions of the diamond film, and performing a selective etching process to remove the exposed portions of the diamond film to form the composite thermal conductor material film with the diamond containing surface.

19. The method of claim 17, wherein forming a composite thermal conductor material film includes forming a diamond film and forming a carbon-based material layer directly on and covering the diamond film.

20. The method of claim 17, further comprising performing a planarization process to planarize the carbon-based material layer to expose portions of the diamond film and form the composite thermal conductor material film with the diamond containing surface.
